(19) United States
(12) Patent Application Publication
(10) Pub. No.: US 2026/0304687 A1
(43) Pub. Date: Oct. 1, 2026

(54) Process and Apparatus for Performing Dual System Hermetic Conduction Heat Transfer

(71) Applicants: Nicholas Glen LITTLETON, Sherwood, OR (US); Gregory William BISSELL, Gilroy, CA (US)

(72) Inventors: Nicholas Glen LITTLETON, Sherwood, OR (US); Gregory William BISSELL, Gilroy, CA (US)

(21) Appl. No.: 19/087,881

(22) Filed: Mar. 27, 2025

(51) Int. Cl. H05K 7/20

(52) U.S. Cl. CPC H05K 7/20254; H05K 7/20772

(57) ABSTRACT

A dual system hermetic thermal transfer apparatus and process for thermal transfer of heat from a primary system to a secondary system via conduction and other equipment that can dissipate this heat to an external source.

### BACKGROUND OF THE INVENTION

### 1. Field of the Invention

The present invention relates to a cooling process and, more particularly, to a cooling process and associated system of hardware for implementing the process.

### 2. Description of the Related Art

It is known that in modern data centers the management of heat generated in the servers is becoming a sever concern in the IT industry. Advancements in chip design and complexity are pushing the power requirements higher which, in turn, creates even more significant cooling requirement. With the oncoming chips that support the conversion to artificial intelligence (AI) data centers, this issue is becoming the primary consideration in the design and performance measurement of the data center.

Many modern AI data centers utilize liquid cooling solutions. These solutions come in many forms and are supported by a variety of hardware configurations. A primary driver of the hardware configuration depends on the facility. Generally, the larger the facility the more built in or hard infrastructure they possess for cooling. Current liquid cooling technologies for data centers are rapidly evolving and most new technologies have moved beyond conventional fans. These new technologies often involve the use of liquid or other specialized solutions that are more effective at heat transfer than blowing air, also known as convection cooling. The two types of liquid cooling that dominate the market are liquid-to-liquid (L2L) and liquid-to-air (L2A). The difference in these systems is where the heat from the server rack is dissipated. In L2L, the heat is channeled from the server rack to a liquid that is then channeled outside the data center to a large-scale facilities type chiller. These chiller units are purpose built as part of the facility. Generally, data centers with this type of liquid cooling are large in scale and have significant land available for facilities infrastructure. L2A systems are designed to channel the heat from a server rack into the air of the data center inside the facility. The air inside the data center is conditioned with a Computer Room Air Conditioner (CRAC). These systems operate much like conventional HVAC systems, but are designed to be much more powerful and move significantly more amounts of air.

Either way, L2L or L2A, liquid pumping and liquid management hardware is required. In data center operations, this hardware is centered around hardware called Coolant Distribution Units (CDUs). CDUs are generally the size of server racks and sit on the floor of the data center adjacent the server racks that are filled with servers for computing. In some cases, these CDUs can take up as much floor space inside the data center as the computing server racks. This is not a desired relationship, because data center operators would much rather have more of the floor space of the data center dedicated to computing vs cooling. The situation gets worse for smaller facilities that do not have access to additional land to build large dedicated liquid chilling capacity. These smaller data centers are forced to operate with L2A CDUs. With the advent of high-powered AI chips, data centers that use L2A CDUs have a 1 -to-1 relationship with a computing server rack and CDU in terms of floor space utilization. That is, half of the floor space of a data center in this configuration is consumed with cooling hardware, which reduces the overall computing capacity of these types of data centers significantly. This issue of CDUs occupying data center floor space also exists with the L2L hardware configuration, however, the impact is not as significant. L2L CDUs can be configured, where the data center can have multiple compute server racks associated with a single L2L CDU. With L2L, the bulk of the liquid handling infrastructure is positioned above the server rack and outside the facility.

In both hardware configurations, it is not desirable to have any additional hardware inside a data center that is not directly executing computing.

Another important operational requirement for data centers is the ability to hot swap a server inside a server rack. Servers often have issues and operational problems that require them to be removed from the server rack for evaluation or repair. The ability to pull a server from the server rack independently from the other servers while the server rack is fully functioning is referred to as hot swapping. This hot swapping capability is made more complicated with liquid cooling. In many situations, the cooling lines that carry cool liquid to the server and heated liquid away from the server are connected to larger manifolds that extend along the back side of the rack. To remove a server from the server rack, these liquid lines must be disconnected. This disconnection comes with a risk of residual liquid in the connector or the line coming from the manifold to spill in the data center. This creates a dangerous situation if any liquid where to come in contact with fully energized equipment, and hinders the ability to fully service the data center efficiently with hot swapping. This line break situation is consistent with either L2L or L2A hardware configurations and represents a significant risk to the data center operations.

It is known that thermal transfer conduction and convection are both mechanisms to transfer heat. Conduction is the process by which heat energy is transferred through a material via direct contact with another material. These materials are often highly thermally conductive metals, such as copper or aluminum. Convection is the process by which heat energy is transferred through the movement of fluids including air, this is often embodied in a fan blowing through a radiator of some kind. Conduction is many times more effective than convention in heat transfer and is the desired solution to provide cooling of components, if feasible. As this relates to server racks and heat management in a data center, the L2L and L2A systems have both conduction and convection process at work. Both systems start with thermal conduction of a cold plate that is in direct contact with the chip in the server that needs to be cooled. After this conduction step both systems utilize convection to remove heat from the server rack. With L2L systems, this convection step sends the heated liquid to an industrial chiller type operation usually outside the data center. With L2A systems, the liquid is pumped through a radiator inside the data center where a large bank of fans cools the liquid via convection. Conduction is many times more effective at heat transfer. As a result, it is advantageous to use this system as much as possible to remove the heat of the server from the data center. It is also advantageous to be able to efficiently hot swap individual servers in a server rack without breaking liquid lines. By enabling a conduction based thermal transfer system at the server rack, data center operations would achieve a more desirable operational condition in both thermal transfer efficiency and effective hot swapping capability.

Another important aspect of conduction is that two systems can transfer heat while each system is independent of each other and both systems are sealed or hermetic. This dual hermetic conduction system can apply to more than merely data centers and server racks. There are many places in industry where heat needs to be moved between to systems and this technology could be applied in similar configurations.

### SUMMARY OF THE INVENTION

Disclosed is a dual system thermal conduction hermetic heat transfer process and associated hardware for implementing the process. The disclosed process is based on the use of two hermetic closed loop cooling systems (a primary and secondary system), which exchange thermal energy through a mechanical conduction interface.

The primary hermetic closed loop system can be associated with the cooling loop of a server blade, where cold plates are put in contact with semiconductor chips that need to have heat removed from them. The primary system can use liquid, refrigerant or other methods to absorb the heat from a chip and move this heat to a heat sink via a closed loop system. The primary system creates the hot heat sink of the conduction heat transfer process.

The secondary hermetic closed loop system is established to absorb the heat from the hot heat sink of the primary system with the cold heat sink of the secondary system. The interface of these two hermetic systems is a mechanical contact of the two heat sinks, where conduction thermal transfer will move the heat from the hot heat sink to the cold heat sink.

The secondary hermetic closed loop system would be associated with and mechanically attached to the server rack where the primary hermetic system is associated with and mechanically attached to the individual server blade that is stacked in the server rack. These two systems are independent of each other, but are mechanically connected and touching for conductive thermal transfer.

The secondary hermetic system can consist of a closed loop cooling system. This system can cycle fluid or refrigerant into a hollow monolith structure on the back of the server rack that can act as a large heat sink for the secondary system. A feature of this monolithic heat sink is the cold heat sink section that interfaces with the primary system hot heat sink associated with the server blade in the server rack. The monolithic heat sink will have significant mass or cooling power to serve as a large cold thermal reservoir such that the entirety of the multiple independent server blades of the rack can dissipate their heat and the entire rack can maintain the appropriate level of conductive thermal transfer to ensure operation of the server rack in its entirety at an optimized temperature.

Once the heat from the servers is conducted into the monolithic heat sink, the primary hermetic closed loop system can operate effectively and maintain the correct temperature of the semiconductor chips in the server. The secondary hermetic closed loop system must maintain a cold enough monolith heat sink by utilizing a closed loop cooling system that can move the heat conducted into the monolith to some other area of the data center or to the outside atmosphere. This closed loop process of the secondary system can be liquid, refrigerant or some other working fluid. The secondary system can dissipate heat via convection with radiator and fan assemblies or the system can interface with a larger facilities-based chiller type heat exchanger. There are many options available for atmospheric heat exchange that could be used. The monolithic heat sink of the secondary system can be provided with insulation of the to prevent heat from entering the data center environment. This insulation can be formed from common insulative materials or the monolithic heat sink can have an attached vacuum sleeve.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

Various embodiments are disclosed in the following detailed description and the accompanying drawings, in which:

FIG. 1A is a schematic of the process depicting the major components in accordance with the invention;

FIG. 2A is a side view of the interface of a cold plate to the semiconductor chip;

FIG. 3A is a view of the interface of multiple primary system hot heat sinks with the secondary system cold heat sink feature of the monolith; and

FIG. 4A is a flow chart of the method in accordance with the invention.

### DETAILED DESCRIPTION OF THE EXEMPLARY EMBODIMENTS

The following detailed description of specific embodiments of the inventive subject matter will be better understood when read in conjunction with the appended drawings. As used herein, an element or step recited in the singular and proceeded with the word “a” or “an” should be understood as not excluding plural of said element or step, unless such exclusion is explicitly stated. Furthermore, references to “embodiment” are not intended to be interpreted as excluding the existence of additional embodiments that also incorporate the recited features. Moreover, unless explicitly stated to the contrary, embodiments “comprising” or “having” an element or a plurality of elements having a particular property may include additional elements not having that property.

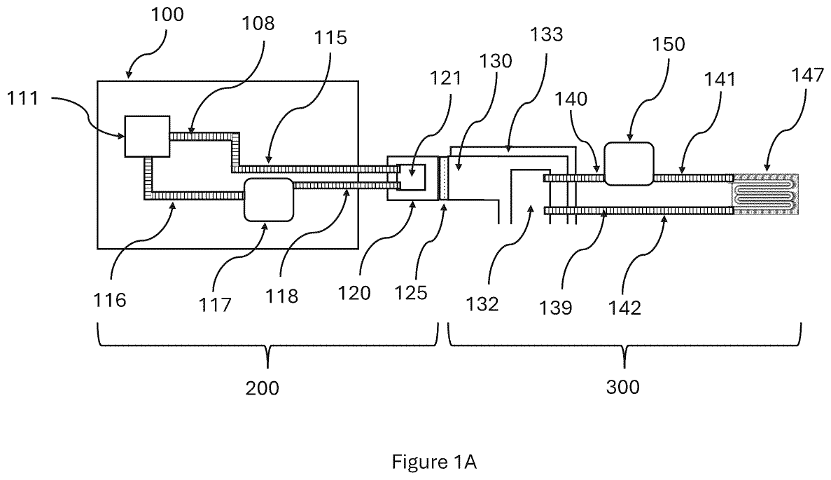

FIG. 1A is a schematic illustration of a hermetic dual system conduction heat exchange process used to transfer heat from individual server blades to a larger monolithic heat sink and an associated process to fully remove the heat from the server rack in accordance with an embodiment of the invention. As shown therein, the system includes a server blade 100. These server blades come in standard sizes and can be configured in many ways inside a server rack. This application can be adopted to any of these configurations, sizes or counts of server blades inside a server rack.

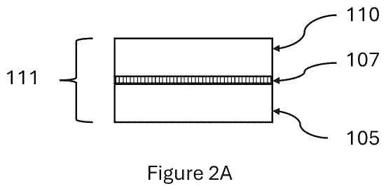

FIG. 2A is a schematic of semiconductor chip 105 in a stack with a cold plate 110 and associated semiconductor chip thermal interface 107. This stack of hardware is a chip cold plate stack 111. Within the server blade 100, there can be multiple chip cold plate stacks 111. The cooling loop for these semiconductor chips 105 has a cold plate 110 that is positioned on top of the chips to absorb the heat from the semiconductor chips 105 during operation.

Returning to FIG. 1A, the heat is absorbed via conduction at the semiconductor chip thermal interface 107 and transferred to a primary thermal transfer liquid 108 that flows through the cold plate 110. This liquid can be aqueous, two phase solution or refrigerant based. The hot primary thermal transfer fluid 108 then flows into a hot side server blade pipe 115. This pipe is connected to the server blade conduction block 120. Inside this block 120 is the hollow server blade conduction cavity 121, where the heated liquid will accumulate and then transfer to the server blade conduction block 120. Once the server blade conduction block 120 is hot, it will transfer this heat to the monolith conduction block 130 through the secondary conduction zone 125 via conduction.

This conduction heat transfer process is what cools the liquid or other thermal transfer fluid used in the server blade 100 to ensure the semiconductor chips 105 can operate at the desired temperature. After the primary thermal transfer fluid 108 is cooled in the server blade conduction block 120, it will travel to the server blade liquid pump 117 via the pump supply pipe 118. The server blade liquid pump 117 can either be within the server blade 100 or can be facilities driven and will service the entire rack with manifolding. The server blade liquid pump 117 could also be a compressor of refrigerant or other fluid transfer solution. The server blade liquid pump 117 will then pump the cooled liquid thermal transfer fluid 108 back to the cold plate 110 via the cold plate supply pipe 116, where the process of heat transfer of the semiconductor chip 105 can start again. This primary system heat exchange hardware 200 in the server blade runs continuously during operation.

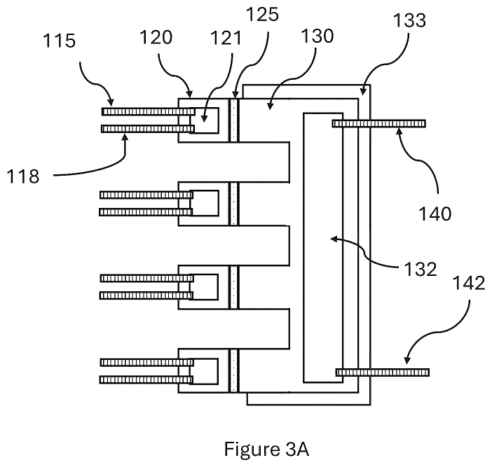

The secondary system heat exchange hardware 300 consists of the monolith conduction block 130 or monolithic heat sink 130 and other additional hardware. This heat sink is metallic or another highly thermally conductive material and has an internal, hollow cavity that serves as a reservoir for the second system thermal transfer fluid 139 or other working fluid to include refrigerant. This fluid is in a cooling loop system of the secondary system heat exchange 300. As shown in FIG. 3A, this monolithic heat sink 130 can have several conduction zones 125 that correspond to a stack of individual server blades 100 in a given server rack.

The monolithic heat sink 130 can also be fully or partially insulated to ensure the heat generated in the system does not escape into the data center. The monolithic heat sink 130 can have an exterior insulation 133, as shown. This insulation can be formed from standard insulative materials or can be a vacuum chamber.

As heat is accumulated in the server blade conduction block 120, it will conduct through the secondary conduction zone 125 and heat up the second system thermal transfer fluid 139. The second system thermal transfer fluid 139 will then flow through the second system radiator supply pipe 142 to the second system radiator 147 where the second system thermal transfer fluid 139 will be cooled via convection or by the designated chilling mechanism of the data center facility. The second system radiator 147 can be any type of heat exchanger commonly used in facilities type heat removal processes. After the second system thermal transfer fluid 139 is chilled, it will flow to the second system pump 150 via the second system pump supply pipe 141. The second system pump can be fluidic or refrigerant or other thermal transfer fluid.

After passing through the pump, the thus chilled second system thermal transfer fluid 139 will flow back to the monolith heat sink 130 via the monolith supply pipe 140. The chilled second system thermal transfer fluid 139 will flow into the monolith thermal cavity 132 where it will absorb the heat from the server blade conduction block 120.

This flow of second system thermal transfer fluid 139 will flow continuously as the secondary system heat exchange hardware 300 will ensure that the primary system heat exchange hardware 200 can maintain the desired temperature of the semiconductor chip 105.

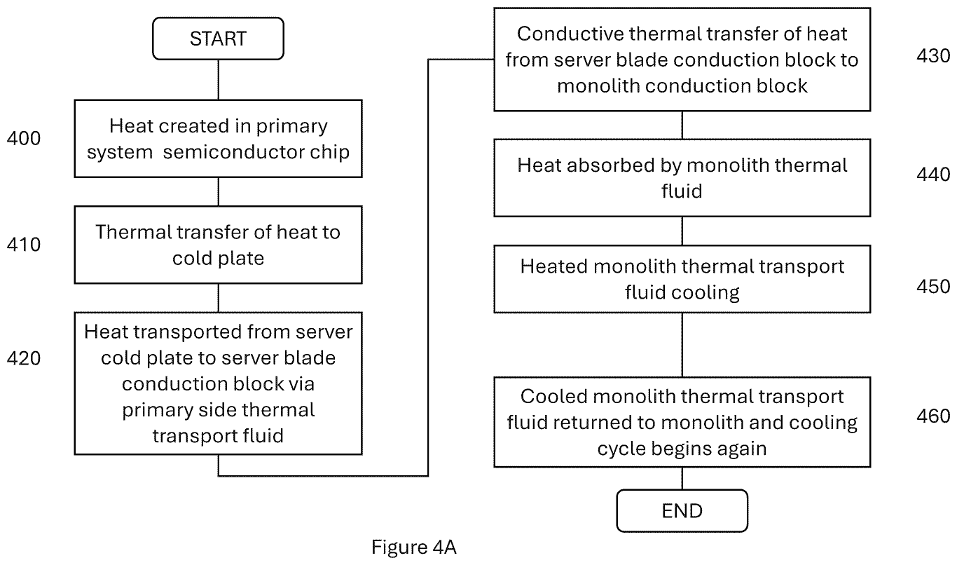

FIG. 4A is a flowchart of the process in accordance with the invention. The method comprises the creation of heat in the semiconductor chip 105, as indicated in step 400.

Next, the heat from the semiconductor chip 105 is thermally conducted into the cold plate 110 through the semiconductor chip thermal interface 107, as indicated in step 410. Once the cold plate 110 has absorbed heat from the semiconductor chip 105 the heat is transported to the server blade conduction block 120 via a flow of primary thermal transport fluid 108, as indicated in step 420. The transport of this fluid is achieved via the server blade liquid pump 117. This server blade liquid pump 117 can either be integrated into the server blade 100 or can be a larger pump that will service multiple individual server blades 100. Once the heat has been transported to the server blade conduction block 120, the heat will conductively transfer to the monolith conduction block 130 via the conduction zone 125, as indicated in step 430.

Once the monolith conduction block 130 acquires the heat from the server blade conduction block 120, the heat is conductively transferred into the second system thermal transfer fluid 139 that is flowing through the monolith thermal cavity 132 as indicated in step 440.

The hot second system thermal transfer fluid 139 is then pumped with the second system pump 150 to the second system radiator 147 or other chiller mechanism per the data center facility. As the second system thermal transfer fluid 139 is flowing through the second system radiator 147, the fluid is cooled via thermal convection or in other chilling methods as dictated by a facility requirement, as indicated in step 450.

After the heat is removed from the second system thermal transfer fluid 139, the cooled fluid is returned to the monolith thermal cavity 132, where the cooling process can start again and operate continuously, as indicated in step 460.

While there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. An apparatus for performing hermetic dual system conduction heat exchange, the apparatus comprising:
a primary system heat exchange stage including at least one server blade having at least one chip cold plate stack, and including at least one conduction block; and
a secondary system heat exchange stage including at least one monolith conduction block thermally coupled to the at least one conduction block of the primary system heat exchange stage.

2. The apparatus as claimed in claim 1, wherein the chip cold plate stack comprises a semiconductor chip arranged in a stack with a cold plate and a thermal interface to form a cooling loop.

3. The apparatus as claimed in claim 1, wherein heat is absorbed via conduction at the thermal interface and transferred to a primary thermal transfer liquid or refrigerant which flows through the cold plate.

4. The apparatus as claimed in claim 1, wherein the at least one conduction block includes a conduction cavity in which heated liquid or refrigerant is accumulated such that heat from the liquid is transferred to the at least one conduction block.

5. The apparatus as claimed in claim 1, further comprising:
a server blade liquid pump or refrigerant compressor which pumps cooled liquid or refrigerant from the at least one conduction block to the at least one chip cold plate stack of the primary system heat exchange stage.

6. The apparatus as claimed in claim 1, wherein the at least one monolith conduction block of the secondary system heat exchange stage includes an insulated hollow cavity which forms a reservoir for a transfer fluid.

7. The apparatus as claimed in claim 6, wherein the at least one monolith conduction block includes at least one conduction zone which corresponds to the at least one server blade.

8. The apparatus as claimed in claim 1, further comprising:
a system radiator or heat exchanger and a system pump or refrigerant compressor arranged in the secondary system heat exchange stage;
wherein heat accumulated in the at least one conduction block is conducted through the at least one secondary conduction zone via a transfer fluid or refrigerant to the system radiator or heat exchanger.

9. A method for performing hermetic dual system conduction heat exchange in an apparatus comprising a primary system heat exchange stage including at least one server blade having at least one chip cold plate stack, and including at least one conduction block, and a secondary system heat exchange stage including at least one monolith conduction block thermally coupled to the at least one conduction block of the primary system heat exchange stage, the method comprising:
thermally conducting heat created by a chip into the at least one chip cold plate via a thermal interface;
transporting heat from the chip absorbed by the at least one chip cold plate to the at least one conduction block via a flow of a primary thermal transport fluid or refrigerant;
transferring the heat conductively from the at least one conduction block to the at least one monolith conduction block via at least one conduction zone;
conductively transferring the heat from the at least one of the monolith conduction block into a secondary thermal transfer fluid or refrigerant flowing through a hollow cavity of the monolith conduction block;
pumping heated second system thermal transfer fluid or refrigerant to a system radiator or a chiller mechanism of a data center facility;
cooling the second thermal transfer fluid or refrigerant while the secondary thermal transfer fluid or refrigerant flows through the system radiator or heat exchanger; and
returning cooled fluid or refrigerant to the monolith thermal cavity after heat is removed from the secondary thermal transfer fluid or refrigerant.

10. The method as claimed in claim 9, wherein the chip cold plate stack comprises a semiconductor chip arranged in a stack with a cold plate and a thermal interface to form a cooling loop.

11. The method as claimed in claim 9, wherein heat is absorbed via conduction at the thermal interface and transferred to the primary thermal transfer fluid or refrigerant which flows through the cold plate.

12. The method as claimed in claim 9, wherein the at least one conduction block includes a conduction cavity in which heated liquid or refrigerant is accumulated such that heat from the liquid or refrigerant is transferred to the at least one conduction block.

13. The method as claimed in claim 9, wherein a server blade liquid pump or refrigerant compressor pumps cooled primary thermal transfer fluid or refrigerant from the at least one conduction block to the at least one chip cold plate stack.

14. The method as claimed in claim 9, wherein the hollow cavity forms a reservoir for the secondary thermal transfer fluid or refrigerant.

15. The method as claimed in claim 14, wherein the at least one monolith conduction block includes at least one conduction zone which corresponds to the at least one server blade.

16. The method as claimed in claim 1, wherein the system radiator or heat exchanger and a system pump or refrigerant compressor are arranged in the secondary system heat exchange stage; and
wherein heat accumulated in the at least one conduction block is conducted through the at least one secondary conduction zone via the secondary thermal transfer fluid or refrigerant to the system radiator or heat exchanger via the system pump or refrigerant compressor.
